(19) United States
(12) Patent Application Publication
(10) Pub. No.: US 2026/0223547 A1
(43) Pub. Date: Jul. 30, 2026

(54) DISPLAY DEVICE AND ELECTRONIC DEVICE INCLUDING THE SAME

(71) Applicant: Samsung Display Co., LTD., Yongin-si (KR)

(72) Inventor: Jae Ik KIM, Yongin-si (KR)

(21) Appl. No.: 19/327,439

(22) Filed: Sep. 12, 2025

(30) Foreign Application Priority Data
Jan. 24, 2025 (KR) 10-2025-0010852

(51) Int. Cl. H10K 59/122; H10K 59/80

(52) U.S. Cl. CPC H10K 59/122; H10K 59/80516

(57) ABSTRACT

A display device in which emission areas and a non-emissive area are defined includes anodes disposed in the emission areas, respectively, and spaced apart from each other, a separator disposed between the anodes in the non-emissive area, and a pixel-defining layer disposed on the anodes and the separator in the non-emissive area. The separator includes a first layer having a first width, a second layer disposed on the first layer and having a second width, and a third layer disposed on the second layer and having a third width.

This application claims priority to Korean Patent Application Number 10-2025-0010852, filed on Jan. 24, 2025, and all the benefits accruing therefrom under 35 U.S.C. § 119, the content of which in its entirety is herein incorporated by reference.

### BACKGROUND

### 1. Field

Embodiments of the disclosure relate to a display device and an electronic device including the display device.

### 2. Related Art

With the development of information technology, the importance of a display device, which is a connection medium between a user and information, is being emphasized. Owing to the importance of display devices, the use of various kinds of display devices, such as a liquid crystal display device and an organic light-emitting display device, is increasing.

### SUMMARY

The disclosure provides a display device and an electronic device including the display device which may reduce or eliminate leakage current generated between sub-pixels next (adjacent) to each other.

An embodiment of the disclosure includes a display device in which emission areas and a non-emissive area are defined. The display device includes anodes disposed in the emission areas, respectively, and spaced apart from each other, a separator disposed between the anodes in the non-emissive area, and a pixel-defining layer disposed on the anodes and the separator in the non-emissive area. The separator includes a first layer having a first width, a second layer disposed on the first layer and having a second width, and a third layer disposed on the second layer and having a third width.

In an embodiment, in the non-emissive area, the anodes may contact at least a portion of the separator.

In an embodiment, the anodes may contact an outer surface of the first layer, an outer surface of the second layer, and a portion of an upper surface and an outer surface of the third layer.

In an embodiment, the pixel-defining layer may contact another portion of the upper surface of the third layer.

In an embodiment, the anodes may contact a portion of an outer surface of the first layer.

In an embodiment, the first layer and the third layer may each include a step.

In an embodiment, the pixel-defining layer may contact another portion of the outer surface of the first layer, an outer surface of the second layer, and a portion of an upper surface and an outer surface of the third layer.

In an embodiment, the anodes may contact a portion of a lower surface of the first layer.

In an embodiment, the pixel-defining layer may contact an outer surface of the first layer, an outer surface of the second layer, and a portion of an upper surface and an outer surface of the third layer.

In an embodiment, in the non-emissive area, the separator may be spaced apart from the anodes.

In an embodiment, at least a portion of the pixel-defining layer may be disposed between the separator and each of the anodes.

In an embodiment, the first width and the third width may be greater than the second width, and the first width may be equal to the third width.

In an embodiment, the first width may be greater than the third width, and the third width may be greater than the second width.

In an embodiment, the third width may be greater than the first width, and the first width may be greater than the second width.

In an embodiment, the third width may be greater than the second width, and the second width may be greater than the first width.

In an embodiment, the display device may further include a light-emitting structure disposed on the anodes, the pixel-defining layer, and the third layer, a cathode on the light-emitting structure, a capping layer on the cathode, and an encapsulation layer on the capping layer.

In an embodiment, the display device may further include an auxiliary electrode disposed between the capping layer and the encapsulation layer.

An embodiment of the disclosure includes an electronic device including a display device in which emission areas and a non-emissive area are defined, and a processor configured to operate the display device. The display device includes anodes disposed in the emission areas, respectively, and spaced apart from each other, a separator disposed between the anodes in the non-emissive area, and a pixel-defining layer disposed on the anodes and the separator in the non-emissive area. The separator includes a first layer having a first width, a second layer disposed on the first layer and having a second width, and a third layer disposed on the second layer and having a third width.

In an embodiment, the anodes may contact at least a portion of the separator.

In an embodiment, the separator may be spaced apart from the anodes.

### BRIEF DESCRIPTION OF THE DRAWINGS

The above and other features of embodiments of the disclosure will become more apparent by describing in further detail embodiments thereof with reference to the accompanying drawings, in which:

FIG. 1 is a block diagram illustrating an embodiment of a display device.

FIG. 2 is a block diagram illustrating an embodiment of a sub-pixel.

FIG. 3 is a plan view illustrating an embodiment of a display panel.

FIG. 4 is a plan view of an embodiment of a pixel.

FIGS. 5 to 13 are cross-sectional views taken along line I-I′ of an embodiment of FIG. 4.

FIG. 14 is a cross-sectional view of an embodiment of a light-emitting structure.

FIG. 15 is a cross-sectional view of an embodiment of a light-emitting structure.

FIGS. 16 to 20 are cross-sectional views schematically illustrating an embodiment of a method of manufacturing a display device.

FIGS. 21 to 25 are cross-sectional views schematically illustrating an embodiment of a method of manufacturing a display device.

FIG. 26 is a block diagram of an embodiment of an electronic device.

FIG. 27 shows schematic views of an embodiment of an electronic device.

### DETAILED DESCRIPTION

The disclosure now will be described more fully hereinafter with reference to the accompanying drawings, in which various embodiments are shown. This disclosure may, however, be embodied in many different forms, and should not be construed as limited to the embodiments set forth herein. Rather, these embodiments are provided so that this disclosure will be thorough and complete, and will fully convey the scope of the disclosure to those skilled in the art.

In describing the drawings, like reference numerals have been used for like elements. In the accompanying drawings, the dimensions of the structures are enlarged than the actual size in order to clearly explain the disclosure. It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element.

The terminology used herein is for the purpose of describing particular embodiments only and is not intended to be limiting. As used herein, “a”, “an”, “the”, and “at least one” do not denote a limitation of quantity, and are intended to include both the singular and plural, unless the context clearly indicates otherwise. For example, “an element” has the same meaning as “at least one element”, unless the context clearly indicates otherwise. “At least one” is not to be construed as limiting “a” or “an”. “Or” means “and/or”. As used herein, the term “and/or” includes any and all combinations of one or more of the associated listed items. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the following description, when a first part is “connected” to a second part, this includes not only the case where the first part is directly connected to the second part, but also the case where a third part is interposed therebetween and they are connected to each other.

Furthermore, relative terms, such as “lower” or “bottom” and “upper” or “top” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower” may therefore, encompasses both an orientation of “lower” and “upper” depending on the particular orientation of the figure. Similarly, when the device in one of the drawing figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Hereinafter, embodiments of the disclosure will be described in detail with reference to the accompanying drawings.

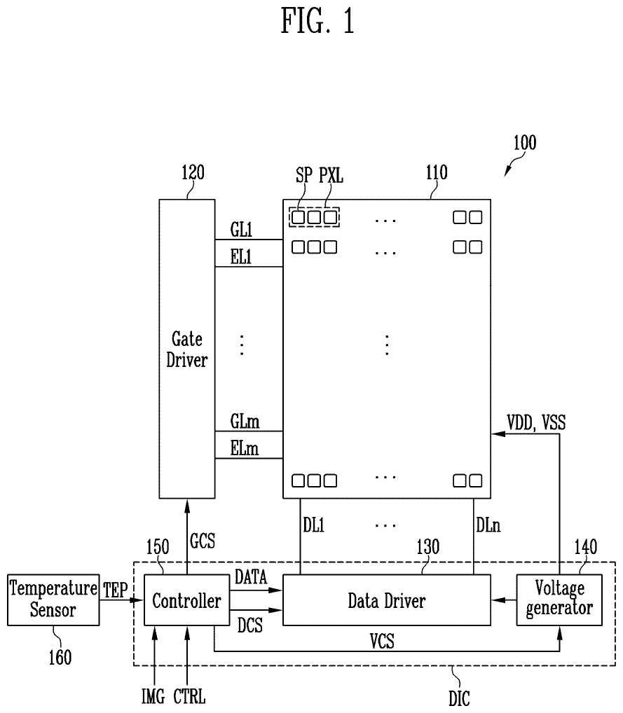

FIG. 1 is a block diagram illustrating an embodiment of a display device.

Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm (m is a natural number). The sub-pixels SP may be connected to the data driver 130 through first to n-th data lines DL1 to DLn (n is a natural number).

Each of the sub-pixels SP may include at least one light-emitting element configured to generate light. Accordingly, each of the sub-pixels SP may generate light in a predetermined color such as red, green, blue, cyan, magenta, or yellow. Two or more sub-pixels among the sub-pixels SP may form one pixel PXL. In an embodiment, as illustrated in FIG. 1, three sub-pixels may form one pixel PXL, for example.

The gate driver 120 may be connected to sub-pixels SP arranged in a row direction through first to m-th gate lines GL1 to GLm. The gate driver 120 may output gate signals to the first to m-th gate lines GL1 to GLm in response to a gate control signal GCS. In an embodiment, the gate control signal GCS may include a start signal which indicates a start of one frame, a horizontal synchronization signal which indicates a start of one horizontal line to synchronize gate signals and data signals, or the like.

There may be further provided first to m-th emission control lines EL1 to ELm connected to the sub-pixels SP in the row direction. In this case, the gate driver 120 may include an emission control driver configured to control the first to m-th emission control lines EL1 to ELm. The emission control driver may operate under the control of the controller 150.

The gate driver 120 may be disposed on one side of the display panel 110. However, the disclosure is not limited to the aforementioned embodiment. In an embodiment, the gate driver 120 may include two or more drivers that are physically and/or logically distinguished from each other, for example. The drivers may be disposed on a first side of the display panel 110 and a second side of the display panel 110 opposite to the first side. As such, the gate driver 120 may be disposed around the display panel 110 in various forms depending on embodiments.

The data driver 130 may be connected to sub-pixels SP arranged in a column direction through the first to n-th data lines DL1 to DLn. The data driver 130 may receive image data DATA and a data control signal DCS from the controller 150. The data driver 130 may operate in response to the data control signal DCS. In an embodiment, the data control signal DCS may include a source start pulse, a source shift clock, a source output enable signal, or the like.

The data driver 130 may apply, using voltages from the voltage generator 140, data signals having grayscale voltages corresponding to the image data DATA to the first to n-th data lines DL1 to DLn. When a gate signal is applied to each of the first to m-th gate lines GL1 to GLm, data signals corresponding to the image data DATA may be applied to the first to n-th data lines DL1 to DLn. Hence, the associated sub-pixels SP may generate light corresponding to the data signals. As a result, images may be displayed on the display panel 110.

The gate driver 120 and the data driver 130 may include complementary metal-oxide semiconductor (“CMOS”) circuit elements.

The voltage generator 140 may operate in response to a voltage control signal VCS provided from the controller 150. The voltage generator 140 generates a plurality of voltages and provide the generated voltages to components of the display device 100. In an embodiment, the voltage generator 140 may receive an input voltage from an external device provided outside the display device 100, adjust the received voltage, and regulate the adjusted voltage, thus generating a plurality of voltages, for example.

The voltage generator 140 may generate a first power voltage VDD and a second power voltage VSS. The generated first and second power voltages VDD and VSS may be provided to the sub-pixels SP. The first power voltage VDD may have a relatively high voltage level. The second power voltage VSS may have a voltage level lower than the first power voltage VDD. However, the disclosure is not limited to the aforementioned embodiment. In an embodiment, the first power voltage VDD or the second power voltage VSS may be provided by an external device of the display device 100, for example.

In addition, the voltage generator 140 may generate various voltages. In an embodiment, the voltage generator 140 may generate an initialization voltage to be applied to the sub-pixels SP, for example. In an embodiment, during a sensing operation for sensing electrical characteristics of transistors and/or light-emitting elements of the sub-pixels SP, a predetermined reference voltage may be applied to each of the first to n-th data lines DL1 to DLn, for example. The voltage generator 140 may generate the reference voltage.

The controller 150 may control overall operations of the display device 100. The controller 150 may receive input image data IMG and a control signal CTRL for controlling an operation of displaying the input image data IMG from an external device. The controller 150 may provide a gate control signal GCS, a data control signal DCS, and a voltage control signal VCS in response to the control signal CTRL.

The controller 150 may convert the input image data IMG to be suitable for the display device 100 or the display panel 110 and then output image data DATA. The controller 150 may align the input image data IMG to be suitable for the sub-pixels SP on a row basis and then output the image data DATA.

Two or more components of the data driver 130, the voltage generator 140, and the controller 150 may be disposed (e.g., mounted) on a single integrated circuit. As illustrated in FIG. 1, the data driver 130, the voltage generator 140, and the controller 150 may be included in a driver integrated circuit DIC. In this case, the data driver 130, the voltage generator 140, and the controller 150 may be components that are functionally separated from each other in the single driver integrated circuit DIC. However, the disclosure is not limited to the aforementioned embodiment. In an embodiment, at least one of the data driver 130, the voltage generator 140, and the controller 150 may be provided as a component separate from the driver integrated circuit DIC, for example.

The display device 100 may include at least one temperature sensor 160. The temperature sensor 160 senses a peripheral temperature and generate temperature data TEP indicating the sensed temperature. In an embodiment, the temperature sensor 160 may be disposed next (adjacent) to the display panel 110 and/or the driver integrated circuit DIC.

The controller 150 may control various operations of the display device 100 in response to the temperature data TEP. In an embodiment, the controller 150 may adjust the luminance of an image outputted from the display panel 110 in response to the temperature data TEP. In an embodiment, the controller 150 may control components such as the data driver 130 and/or the voltage generator 140, thus adjusting data signals and the first and second power voltages VDD and VSS, for example.

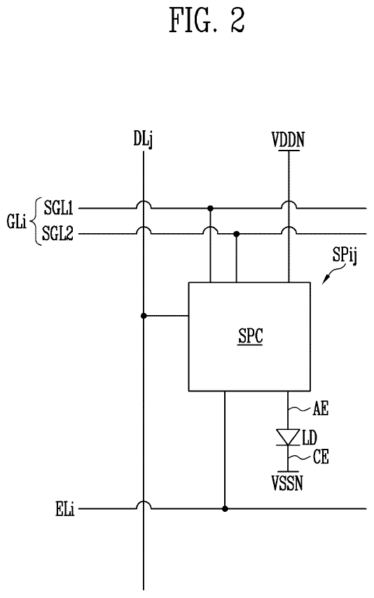

FIG. 2 is a block diagram illustrating an embodiment of a sub-pixel.

In FIG. 2, a sub-pixel SPij which is disposed on an i-th row (where i is an integer equal to or greater than 1 and less than or equal to m) and a j-th column (where j is an integer equal to or greater than 1 and less than or equal to n) among the sub-pixels SP of FIG. 1 is illustrated.

Referring to FIG. 2, the sub-pixel SPij may include a sub-pixel circuit SPC and a light-emitting element LD.

The light-emitting element LD is connected between a first power voltage node VDDN and a second power voltage node VSSN. Here, the first power voltage node VDDN may be a node transmitting the first power voltage VDD of FIG. 1. The second power voltage node VSSN may be a node transmitting the second power voltage VSS of FIG. 1.

An anode AE of the light-emitting element LD may be connected to the first power voltage node VDDN through the sub-pixel circuit SPC. A cathode CE of the light-emitting element LD may be connected to the second power voltage node VSSN. In an embodiment, the anode AE of the light-emitting element LD may be connected to the first power voltage node VDDN through one or more transistors included in the sub-pixel circuit SPC, for example.

The sub-pixel circuit SPC may be connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC controls the light-emitting element LD in response to signals received through the aforementioned signal lines.

The sub-pixel circuit SPC may operate in response to a gate signal received through the i-th gate line GLi. The i-th gate line GLi may include one or more sub-gate lines. In an embodiment, as illustrated in FIG. 2, the i-th gate line GLi may include first and second sub-gate lines SGL1 and SGL2. The sub-pixel circuit SPC may operate in response to gate signals received through the first and second sub-gate lines SGL1 and SGL2. As such, in the case where the i-th gate line GLi includes two or more sub-gate lines, the sub-pixel circuit SPC may operate in response to gate signals received through the corresponding sub-gate lines.

The sub-pixel circuit SPC may operate in response to an emission control signal received through the i-th emission control line ELi. In an embodiment, the i-th emission control line ELi may include one or more sub-emission control lines. In the case where the i-th emission control line ELi includes two or more sub-emission control lines, the sub-pixel circuit SPC may operate in response to emission control signals received through the corresponding sub-emission control lines.

The sub-pixel circuit SPC may receive a data signal through a j-th data line DLj. The sub-pixel circuit SPC may store a voltage corresponding to the data signal in response to at least one of gate signals received through the first and second sub-gate lines SGL1 and SGL2. The sub-pixel circuit SPC may adjust current flowing from the first power voltage node VDDN to the second power voltage node VSSN through the light-emitting element LD according to the stored voltage in response to the emission control signal received through the i-th emission control line ELi. Therefore, the light-emitting element LD may emit light with a luminance corresponding to the data signal.

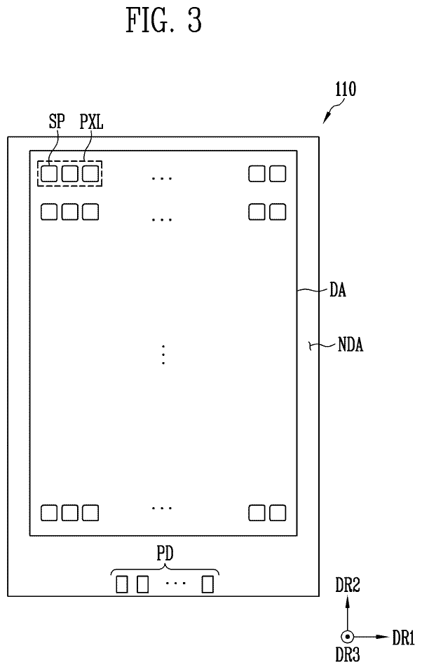

FIG. 3 is a plan view illustrating an embodiment of a display panel.

Referring to FIG. 3, the display panel 110 may include a display area DA and a non-display area NDA. The display panel 110 may display images through the display area DA. The non-display area NDA may be disposed around the display area DA.

The display panel 110 may include the sub-pixels SP and pads PD.

The sub-pixels SP may be disposed in the display area DA. The sub-pixels SP may be arranged in the form of a matrix along a first direction DR1 and a second direction DR2 intersecting with the first direction DR1. However, the disclosure is not limited to the aforementioned embodiment. In an embodiment, the sub-pixels SP may be arranged in a zigzag pattern in the first direction DR1 and the second direction DR2, for example. In an embodiment, the sub-pixels SP may be arranged in a PENTILE™ pattern, for example. The first direction DR1 may refer to a row direction and the second direction DR2 may refer to a column direction.

Components for controlling the sub-pixels SP may be disposed in the non-display area NDA. In an embodiment, lines such as the first to m-th gate lines GL1 to GLm and the first to n-th data lines DL1 to DLn connected to the sub-pixels SP of FIG. 1 may be disposed in the non-display area NDA, for example.

At least one of the gate driver 120, the data driver 130, the voltage generator 140, the controller 150, and the temperature sensor 160 of FIG. 1 may be integrated in the non-display area NDA. The gate driver 120 of FIG. 1 may be disposed (e.g., mounted) on the display panel 110 and disposed in the non-display area NDA. However, the disclosure is not limited to the aforementioned embodiment. In an embodiment, the gate driver 120 may be implemented as an integrated circuit separate from the display panel 110, for example. The temperature sensor 160 may be disposed in the non-display area NDA to sense the temperature of the display panel 110.

The pads PD may be disposed in the non-display area NDA. The pads PD may be electrically connected to the sub-pixels SP through signal lines. In an embodiment, the pads PD may be connected to the sub-pixels SP through the first to n-th data lines DL1 to DLn (refer to FIG. 1), for example.

The display panel 110 may be connected to other components of the display device 100 (refer to FIG. 1) through pads PD. Voltages and signals desired for the operation of the components included in the display panel 110 may be provided through the pads PD from the driver integrated circuit DIC of FIG. 1. In an embodiment, the first to n-th data lines DL1 to DLn may be connected to the driver integrated circuit DIC through the pads PD, for example. In an embodiment, the first and second power voltages VDD and VSS may be received from the driver integrated circuit DIC through the pads PD, for example. In an embodiment, in the case where the gate driver 120 is disposed (e.g., mounted) on the display panel 110, the gate control signal GCS may be transmitted from the driver integrated circuit DIC to the gate driver 120 through the pads PD, for example.

A circuit board may be electrically connected to the pads PD by a conductive adhesive component such as an anisotropic conductive film. Here, the circuit board may be a flexible circuit board or flexible film that includes or consists of flexible material. The driver integrated circuit DIC may be disposed (e.g., mounted) on the circuit board and be electrically connected to the pads PD.

The display area DA may have various shapes. The display area DA may have a closed-loop shape including linear and/or curved sides. In an embodiment, the display area DA may have shapes such as a polygon, a circle, a semicircle, and an ellipse, for example.

The display panel 110 may include a planar display surface. However, the disclosure is not limited to the aforementioned embodiment. In an embodiment, the display panel 110 may include a display surface that is at least partially rounded, for example. The display panel 110 may be bendable, foldable, or rollable. In the aforementioned cases, the display panel 110 may include materials having flexible properties.

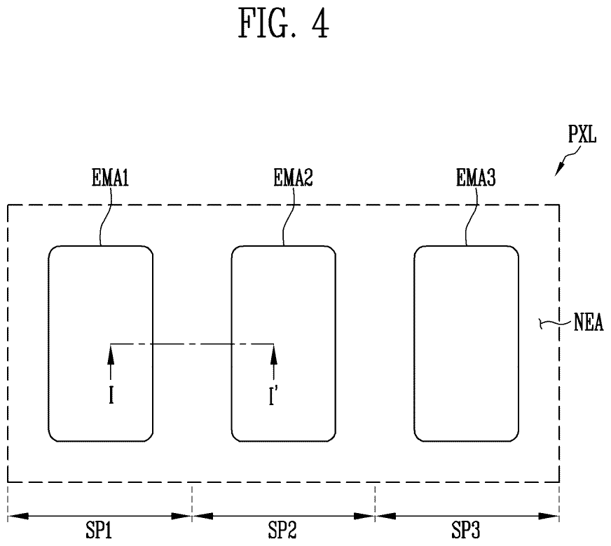

FIG. 4 is a plan view of an embodiment of a pixel.

Referring to FIG. 4, the pixel PXL may include first to third sub-pixels SP1 to SP3 arranged along the first direction DR1. However, the disclosure is not limited to the aforementioned embodiment. In an embodiment, the first sub-pixel SP1 and the second sub-pixel SP2 may be arranged along the second direction DR2, and the third sub-pixel SP3 may be disposed along the first direction DR1 with respect to each of the first and second sub-pixels SP1 and SP2, for example. In an embodiment, the first and third sub-pixels SP1, SP3 may be arranged along the first direction DR1, and the second sub-pixel SP2 may be disposed along a direction (e.g., a diagonal direction) inclined by an acute angle based on the second direction DR2, with respect to the first sub-pixel SP1, for example.

The first sub-pixel SP1 may include a first emission area EMA1, and a non-emission area NEA at the periphery of the first emission area EMA1. The second sub-pixel SP2 may include a second emission area EMA2, and the non-emission area NEA at the periphery of the second emission area EMA2. The third sub-pixel SP3 may include a third emission area EMA3, and the non-emission area NEA at the periphery of the third emission area EMA3.

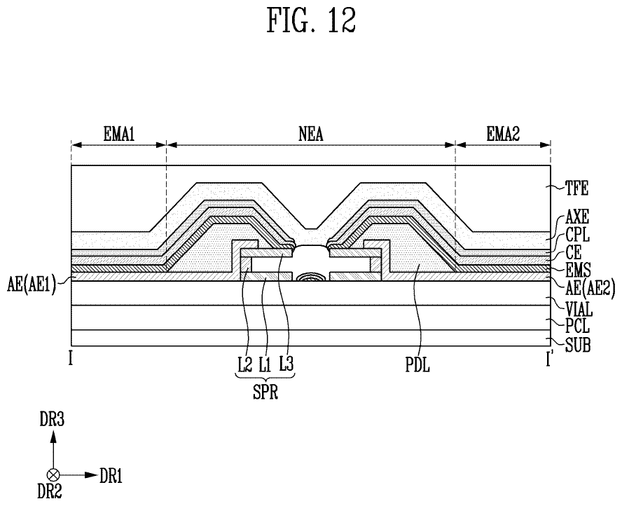

The first emission area EMA1 may be an area in which light is emitted from a portion of a light-emitting structure EMS (refer to FIG. 12), which corresponds to the first sub-pixel SP1. The second emission area EMA2 may be an area in which light is emitted from a portion of the light-emitting structure EMS, which corresponds to the second sub-pixel SP2. The third emission area EMA3 may be an area in which light is emitted from a portion of the light-emitting structure EMS, which corresponds to the third sub-pixel SP3.

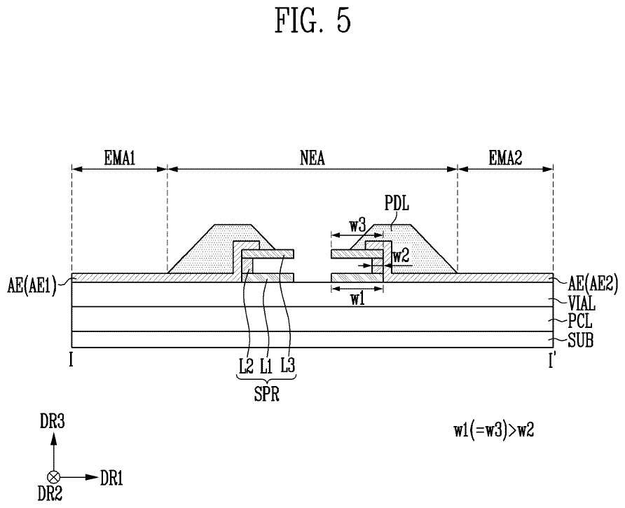

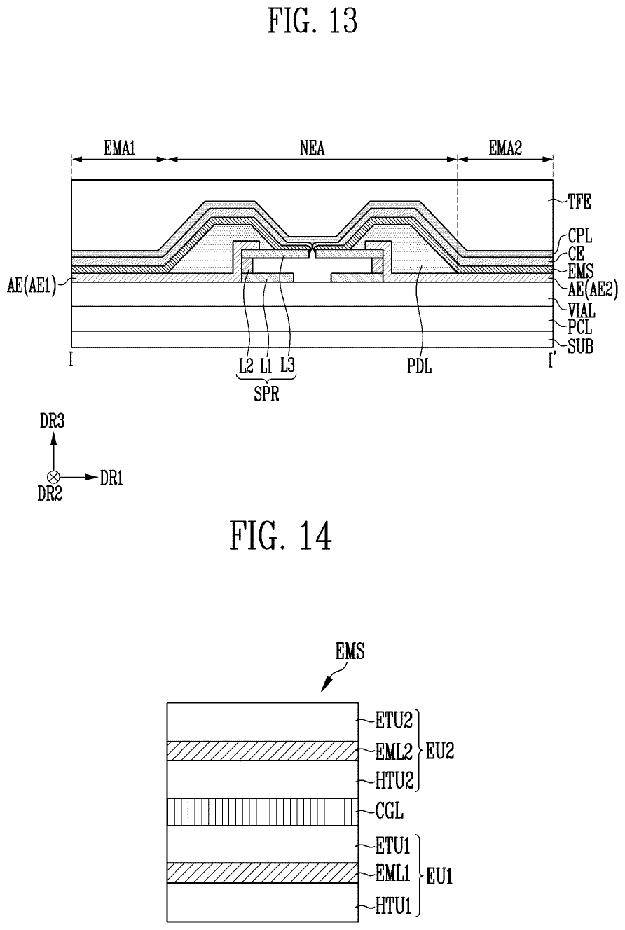

FIGS. 5 to 13 are cross-sectional views taken along line I-I′ of an embodiment of FIG. 4. In FIGS. 5 to 12, a substrate SUB, a pixel circuit layer PCL, a via layer VIAL, anodes AE, a separator SPR, and a pixel-defining layer PDL are mainly shown. In FIGS. 12 and 13, a light-emitting structure EMS, a cathode CE, a capping layer CPL, an auxiliary electrode AXE, and an encapsulation layer TFE are additionally shown.

Referring to FIG. 5, the substrate SUB may be a silicon wafer substrate formed using a semiconductor process. In an embodiment, the substrate SUB may include silicon, germanium, and/or silicon-germanium, for example. However, the disclosure is not limited to the aforementioned embodiment. In an embodiment, the substrate SUB may be a glass substrate or a polyimide (“PI”) substrate, for example.

The pixel circuit layer PCL may be disposed on the substrate SUB. The pixel circuit layer PCL may include circuit elements of the first and second sub-pixels SP1 and SP2 (refer to FIG. 4). In an embodiment, the pixel circuit layer PCL may include transistors and one or more capacitors included in a sub-pixel circuit SPC (refer to FIG. 2) of the first sub-pixel SP1, and transistors and one or more capacitors included in a sub-pixel circuit SPC of the second sub-pixel SP2, for example.

The via layer VIAL may be disposed on the pixel circuit layer PCL. The via layer VIAL may planarize or substantially planarize step differences on the pixel circuit layer PCL. In an embodiment, the via layer VIAL covers the pixel circuit layer PCL, and may have an entirely flat or substantially flat surface, for example. The via layer VIAL may include at least one of silicon oxide (SiOₓ), silicon nitride (SiNₓ), and silicon carbon nitride (SiCN), but the disclosure is not limited to the aforementioned embodiment.

The separator SPR may be disposed in the non-emission area NEA. In an embodiment, the separator SPR may be disposed on the via layer VIAL in the non-emission area NEA, for example. The separator SPR may be disposed between the anodes AE in the non-emission area NEA. The separator SPR may have a multi-layered structure. In an embodiment, the separator SPR may include a first layer L1, a second layer L2, and a third layer L3, which are stacked along the third direction DR3, for example. In other words, the separator SPR may have a triple-layered structure.

The first layer L1 may be disposed on a portion of the via layer VIAL. The first layer L1 may include at least one of an organic material, an inorganic material, and a metal. The first layer L1 may have a first width w1 defined in the first direction DR1.

The second layer L2 may be disposed on a portion of the first layer L1. The second layer L2 may include at least one of an organic material, an inorganic material, and a metal. The second layer L2 may have a second width w2 defined in the first direction DR1. In an embodiment, the second width w2 may be less than the first width w1. In an embodiment, the second layer L2 may have a structure that is recessed outward relative to the first layer L1, for example.

The third layer L3 may be disposed on the second layer L2. The third layer L3 may include at least one of an organic material, an inorganic material, and a metal. The third layer L3 may have a third width w3 defined in the first direction DR1. In an embodiment, the third width w3 may be greater than the second width w2. In an embodiment, the third layer L3 may have a structure that protrudes inward relative to the second layer L2, for example. Accordingly, the second layer L2 and the third layer L3 may form an undercut structure. In an embodiment, the third width w3 may be equal to the first width w1.

The anodes AE may be disposed on the via layer VIAL and spaced apart from each other. The anodes AE may each be disposed in a corresponding emission area. In an embodiment, the first anode AE1 may be disposed in the first emission area EMA1, and the second anode AE2 may be disposed in the second emission area EMA2, for example. Accordingly, the first and second anodes AE1 and AE2 may be spaced apart from each other. The anodes AE may be disposed in the non-emissive area NEA. In an embodiment, the anodes AE may contact at least a portion of the separator SPR in the non-emissive area NEA. In an embodiment, in the non-emissive area NEA, the anodes AE may contact an outer surface of the first layer L1, an outer surface of the second layer L2, and a portion of an upper surface and an outer surface of the third layer L3, for example. In other words, in the non-emissive area NEA, the anodes AE may include a step, cover a side of the separator SPR, and cover a portion of an upper surface of the separator SPR.

The first anode AE1 may be included in the first sub-pixel SP1 (refer to FIG. 4), and the second anode AE2 may be included in the second sub-pixel SP2 (refer to FIG. 4). The first anode AE1 may be connected to the sub-pixel circuit SPC of the first sub-pixel SP1 included in the pixel circuit layer PCL through a first contact hole penetrating through the via layer VIAL. The second anode AE2 may be connected to the sub-pixel circuit SPC of the second sub-pixel SP2 included in the pixel circuit layer PCL through a second contact hole penetrating through the via layer VIAL.

The anodes AE may include a transparent conductive material. In an embodiment, the anodes AE may include at least one of indium tin oxide (“ITO”), indium zinc oxide (“IZO”), zinc oxide (ZnO), indium gallium zinc oxide (“IGZO”), and indium tin zinc oxide (“ITZO”), for example, but the disclosure is not limited to the aforementioned embodiment. The anodes AE may have a single-layered structure or a multi-layered structure including one or more of the above-described materials.

The pixel-defining layer PDL may be disposed on the anodes AE and the separator SPR in the non-emissive area NEA. In an embodiment, the pixel-defining layer PDL may contact side and upper surfaces of the anodes AE in the non-emissive area NEA, and may contact another portion of the upper surface of the third layer L3. In other words, in the non-emission area NEA, the pixel-defining layer PDL covers the anodes AE including a step and may cover another portion of the upper surface of the separator SPR.

The pixel-defining layer PDL may define openings that partially expose the anodes AE. The pixel-defining layer PDL may include an entirely flat or substantially flat surface. The pixel-defining layer PDL may include an inorganic insulating material. In an embodiment, the pixel-defining layer PDL may include at least one of silicon oxide (SiOx) and silicon nitride (SiNx), for example. However, the disclosure is not limited to the aforementioned embodiment. In an embodiment, the pixel-defining layer PDL may include at least one of organic insulating materials, such as polyimide, polyamide, acrylic resin, benzocyclobutene, and phenolic resin, for example. The pixel-defining layer PDL may have a single-layered structure or a multi-layered structure including one or more of the above-described materials.

So far, sub-pixels next (adjacent) to each other, e.g., the first and second sub-pixels SP1 and SP2 in FIG. 4, have been described. The sub-pixels next (adjacent) to each other in FIG. 4, e.g., the second and third sub-pixels SP2 and SP3, may also be configured as described above, unless otherwise specified herein.

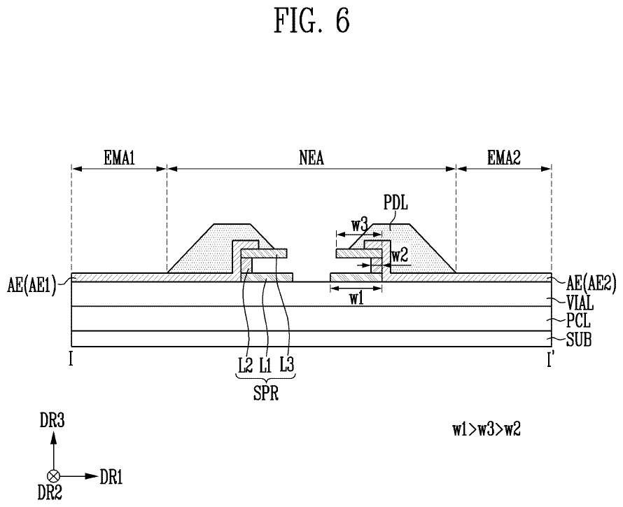

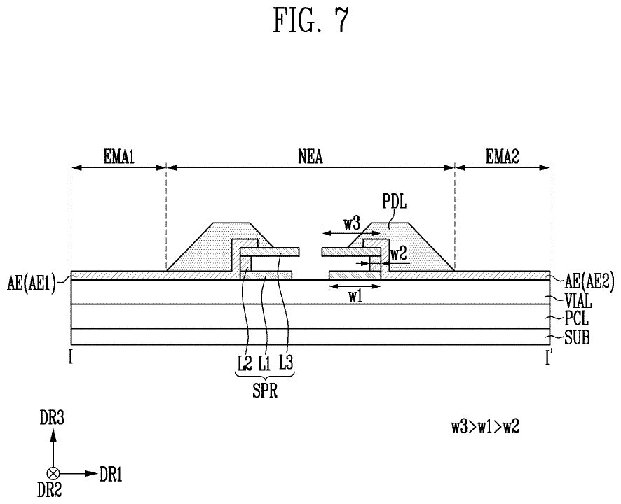

In FIGS. 6 and 7, the explanation of the content overlapping with FIG. 5 shall be omitted. Referring to FIGS. 6 and 7, the third width w3 of the third layer L3 of the separator SPR may be varied. In an embodiment, as shown in FIG. 6, the third width w3 of the third layer L3 may be less than the first width w1 of the first layer L1, for example. Also, as shown in FIG. 7, the third width w3 of the third layer L3 may be greater than the first width w1 of the first layer L1.

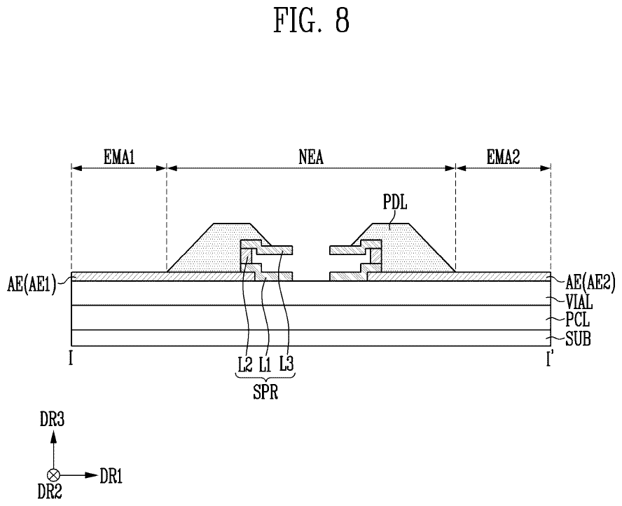

In FIG. 8, the explanation of the content overlapping with FIG. 5 shall be omitted. Referring to FIG. 8, the first layer L1 of the separator SPR may be disposed on a portion of the via layer VIAL and portions of the anodes AE. In an embodiment, the first layer L1 may include a step in the non-emissive area NEA and cover portions of the anodes AE, for example. As shown in FIG. 8, the anodes AE may only contact the first layer L1 of the separator SPR in the non-emissive area NEA. In an embodiment, the anodes AE may contact a portion of the outer surface of the first layer L1 in the non-emissive area NEA, for example. Similar to the first layer L1, the third layer L3 may include a step. In FIG. 8, the second layer L2 of the separator SPR is shown spaced apart from the steps of the first and third layers L1 and L3, but the disclosure is not limited to the aforementioned embodiment. In an embodiment, the second layer L2 may be next (adjacent) to the steps of the first and third layers L1 and L3, for example.

In an embodiment, the pixel-defining layer PDL may contact the upper surfaces of the anodes AE, another portion of the outer surface of the first layer L1, the outer surface of the second layer L2, and a portion of the upper surface and the outer surface of the third layer L3 in the non-emissive area NEA. In other words, in the non-emissive area NEA, the pixel-defining layer PDL may cover the upper surfaces of the anodes AE and the step of the upper surface and outer surface of the separator SPR.

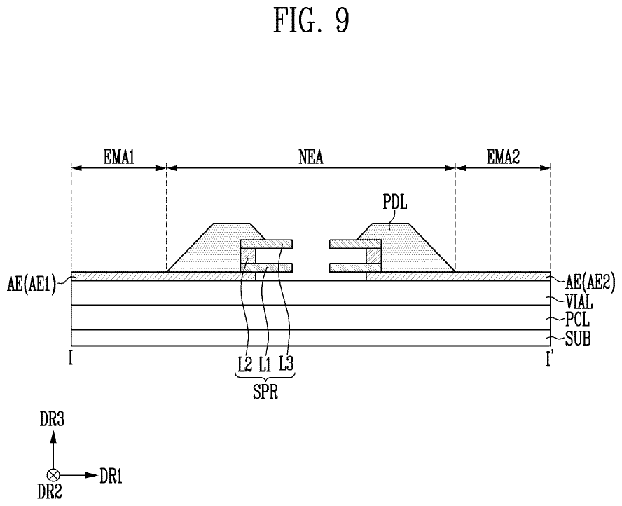

In FIG. 9, the explanation of the content overlapping with FIG. 5 shall be omitted. Referring to FIG. 9, the separator SPR may be disposed on the anodes AE. In an embodiment, in the non-emissive area NEA, the anodes AE may contact a portion of the lower surface of the first layer L1, for example. In the non-emissive area NEA, the first layer L1 may have a structure that protrudes inward relative to the anodes AE. In other words, the anodes AE may not be disposed between the protruding portion of the first layer L1 and the via layer VIAL.

In an embodiment, the pixel-defining layer PDL may contact the upper surfaces of the anodes AE, the outer surface of the first layer L1, the outer surface of second layer L2, and a portion of the upper surface and the outer surface of third layer L3 in the non-emissive area NEA. In other words, in the non-emission area NEA, the pixel-defining layer PDL may cover the upper surfaces of the anodes AE and a portion of the upper surface and the outer surface of the separator SPR.

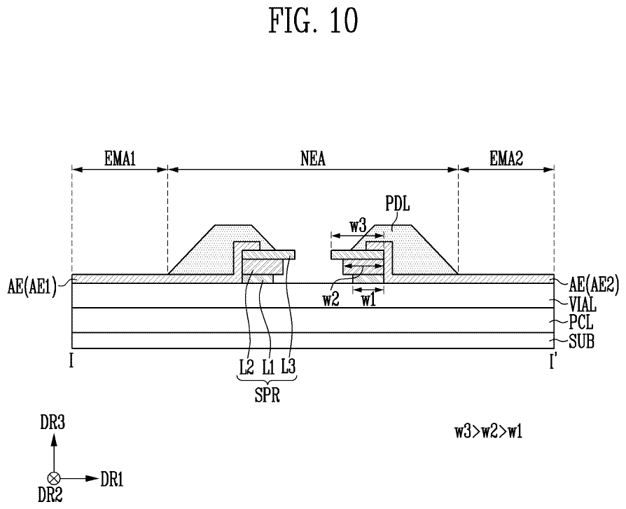

In FIG. 10, the explanation of the content overlapping with FIG. 5 shall be omitted. Referring to FIG. 10, a width of the separator SPR may increase along the third direction DR3. In an embodiment, the first width w1 of the first layer L1 may be less than the second width w2 of the second layer L2, and the second width w1 of the second layer L2 may be less than the third width w3 of the third layer L3, for example. In other words, the separator SPR may have an inverted pyramidal structure whose width increases in the third direction DR3.

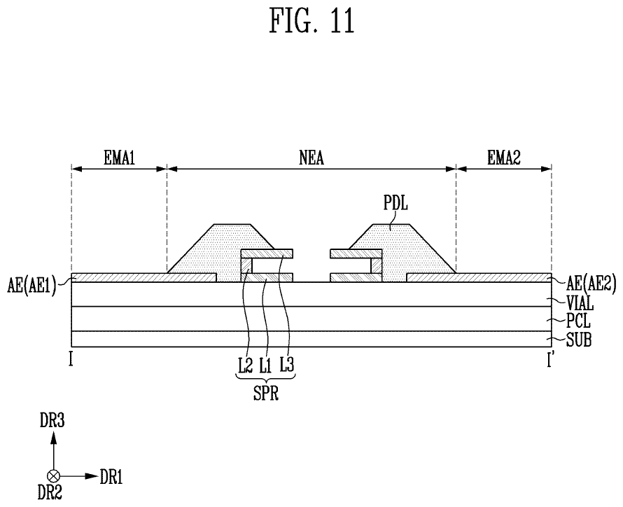

In FIG. 11, the explanation of the content overlapping with FIG. 5 shall be omitted. Referring to FIG. 11, in an embodiment, the anodes AE may be spaced apart from the separator SPR in the non-emissive area NEA. In an embodiment, the anodes AE may be spaced apart from the separator SPR along the first direction DR1 in the non-emissive area NEA, for example. In other words, the anodes AE may not contact the separator SPR in the non-emissive area NEA.

In an embodiment, at least a portion of the pixel-defining layer PDL may be disposed between the separator SPR and each of the anodes AE in the non-emissive area NEA. In an embodiment, the pixel-defining layer PDL may contact upper surfaces and side surfaces of the anodes AE, the outer surface of the first layer L1, the outer surface of a second layer L2, and a portion of the upper surface and the outer surface of a third layer L3 in the non-emissive area NEA, for example. In other words, at least a portion of the pixel-defining layer PDL may be disposed in a space between the separator SPR and each of the anodes AE in the non-emissive area NEA.

In FIG. 12, the explanation of the content overlapping with FIG. 5 shall be omitted. Referring to FIG. 12, the light-emitting structure EMS may be disposed on the anodes AE, the pixel-defining layer PDL, and the separator SPR (or the third layer L3). The light-emitting structure EMS may be disposed discontinuously in the non-emissive area NEA. In an embodiment, at least a portion of the light-emitting structure EMS may be disconnected by the separator SPR disposed in the non-emissive area NEA, for example. In an embodiment, a highly conductive layer (e.g., charge generation layer CGL of FIG. 14) of the light-emitting structure EMS may be disconnected in the non-emissive area NEA, for example. Accordingly, leakage current generated between sub-pixels next (adjacent) to each other (e.g., the first and second sub-pixels SP1 and SP2 of FIG. 4) through the highly conductive layer of the light-emitting structure EMS may be reduced or eliminated. In addition, since at least a part of the light-emitting structure EMS is disconnected in the non-emissive area NEA, the display quality may be improved in the first and second emission areas EMA1 and EMA2 without deteriorating the performance of the light-emitting structure EMS.

The cathode CE may be disposed on the light-emitting structure EMS. In an embodiment, the cathode CE may be disposed discontinuously in the non-emissive area NEA. In an embodiment, the cathode CE may be disconnected by the separator SPR disposed in the non-emissive area NEA, for example. The cathode CE may be substantially transparent or translucent to satisfy a desired light transmittance (e.g., a predetermined light transmittance). In an embodiment, the cathode CE may include at least one of transparent conductive materials, such as indium tin oxide (“ITO”), zinc oxide (ZnO), indium gallium zinc oxide (“IGZO”), and indium tin zinc oxide (“ITZO”), for example. The cathode CE may have a single-layered structure or a multi-layered structure including one or more of the above-described materials.

The capping layer CPL may be disposed on the cathode CE. In an embodiment, the capping layer CPL may be disposed discontinuously in the non-emissive area NEA. In an embodiment, the capping layer CPL may be disconnected by the separator SPR disposed in the non-emissive area NEA, for example. The capping layer CPL may protect the components under the capping layer CPL, such as the cathode CE and the light-emitting structure EMS, from external moisture, humidity, or the like. The capping layer CPL may include at least one of silicon nitride (SiNₓ), silicon oxide (SiOₓ), silicon oxynitride (SiOₓN_{y}), a metal oxide, and aluminum oxide (AlOₓ). However, the disclosure is not limited to the aforementioned embodiment. The capping layer CPL may have a single-layered structure or a multi-layered structure including one or more of the above-described materials.

The auxiliary electrode AXE may be disposed on the capping layer CPL. The auxiliary electrode AXE may contact the cathode CE in the non-emissive area NEA. As the auxiliary electrode AXE is connected to cathode CE with weak connection due to disconnection by the separator SPR, the operation reliability of the display device 100 (refer to FIG. 1) may be increased. The auxiliary electrode AXE may include a transparent conductive material. In an embodiment, the auxiliary electrode AXE may include at least one of transparent conductive materials, such as indium tin oxide (“ITO”), indium zinc oxide (“IZO”), zinc oxide (ZnO), indium gallium zinc oxide (“IGZO”), and indium tin zinc oxide (“ITZO”), for example. However, the embodiments are not necessarily limited thereto.

The encapsulation layer TFE may be disposed on the auxiliary electrode AXE. The encapsulation layer TFE may prevent or substantially prevent the infiltration of oxygen and/or moisture. The encapsulation layer TFE may include a structure in which one or more inorganic layers and one or more organic layers are alternately stacked. In an embodiment, the inorganic layer may include an inorganic insulating material, such as silicon nitride (SiNₓ), silicon oxide (SiOₓ), or silicon oxynitride (SiOₓN_{y}), for example. In an embodiment, the organic layer may include an organic insulating material, such as an acrylic resin, an epoxy resin, a phenolic resin, a polyamide resin, a polyimide resin, an unsaturated polyester resin, a polyphenylenether resin, a polyphenylenefulfide resin, or benzocyclobutene, for example. However, the disclosure is not limited to the aforementioned embodiment.

In FIG. 13, the explanation of the content overlapping with FIGS. 5 and 12 shall be omitted. Referring to FIG. 13, in an embodiment, the light-emitting structure EMS may be disposed discontinuously and the cathode CE may be disposed continuously in the non-emissive area NEA. In an embodiment, at least a portion of the light-emitting structure EMS may be disconnected by the separator SPR disposed in the non-emissive area NEA and the cathode CE may not be disconnected, for example. Depending on the specifications of the separator SPR disposed in the non-emissive area NEA, it may be determined whether the cathode CE is disconnected or not. In an embodiment, as shown in FIG. 13, the larger the width of the upper surface of the separator SPR (or the third width w3 of the third layer L3 of FIG. 7), the more likely the cathode CE is not disconnected, for example. However, the disclosure is not limited to the aforementioned embodiment, and whether the cathode CE is disconnected or not may be determined depending on the thickness, shape, or the like of the separator SPR.

The auxiliary electrode AXE in FIG. 12 may be omitted because the cathode CE is continuously disposed in the non-emissive area NEA to maintain connectivity.

FIG. 14 is a cross-sectional view of an embodiment of a light-emitting structure.

Referring to FIG. 14, the light-emitting structure EMS may have a tandem structure in which the first and second light-emitting units EU1 and EU2 are stacked. In other words, the light-emitting structure EMS may have a two stack tandem structure.

Each of the first and second light-emitting units EU1 and EU2 may include at least one light-emitting layer which generates light according to the applied current. The first light-emitting unit EU1 may include a first light-emitting layer EML1, a first electron-transporting unit ETU1, and a first hole-transporting unit HTU1. The first light-emitting layer EML1 may be disposed between the first electron-transporting unit ETU1 and the first hole-transporting unit HTU1. The second light-emitting unit EU2 may include a second light-emitting layer EML2, a second electron-transporting unit ETU2, and a second hole-transporting unit HTU2. The second light-emitting layer EML2 may be disposed between the second electron-transporting unit ETU2 and the second hole-transporting unit HTU2.

Each of the first and second hole-transporting units HTU1 and HTU2 may include at least one of a hole injection layer and a hole transport layer, and may further include a hole buffer layer, an electron-blocking layer, or the like as desired. The first and second hole-transporting units HTU1 and HTU2 may have the same configuration or different configurations from each other.

Each of the first and second electron-transporting units ETU1 and ETU2 may include at least one of an electron injection layer and an electron transport layer, and may further include an electron buffer layer, a hole-blocking layer, or the like as desired. The first and second electron-transporting units ETU1 and ETU2 may have the same configuration or different configurations from each other.

A connecting layer, which may be provided in a form of the charge generation layer CGL, may be disposed between the first and second light-emitting units EU1 and EU2 to connect them to one another. The charge generation layer CGL may have a stacked-layered structure of a p-dopant layer and a n-dopant layer. In an embodiment, the p-dopant layer may include p-type dopants such as HAT-CN, TCNQ, NDP-9, etc., and the n-dopant layer may include alkali metals, alkaline earth metals, lanthanide-based metals, or combinations thereof, for example. However, the disclosure is not limited to the aforementioned embodiment.

The first light-emitting layer EML1 and the second light-emitting layer EML2 may generate light of different colors. The light emitted from each of the first light-emitting layer EML1 and the second light-emitting layer EML2 may be mixed and visually recognized as white light. In an embodiment, the first light-emitting layer EML1 may generate blue light, and the second light-emitting layer EML2 may generate yellow light, for example. The second light-emitting layer EML2 may include a structure in which a first sub-light-emitting layer configured to generate red light and a second sub-light-emitting layer configured to generate green light are stacked. The red light and the green light may be mixed to provide yellow light. In this case, an intermediate layer configured to perform a function of transporting holes and/or a function of blocking the transport of electrons may be disposed between the first and second sub-light-emitting layers. However, the disclosure is not limited to the aforementioned embodiment, and the first light-emitting layer EML1 and the second light-emitting layer EML2 may generate light of a same color.

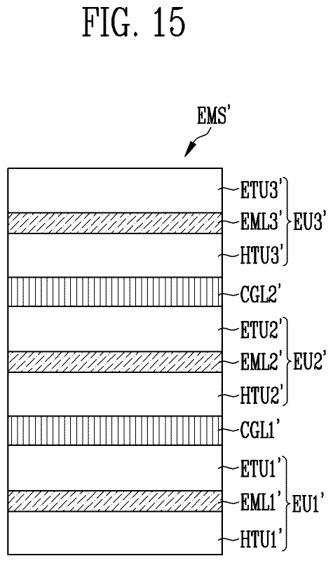

FIG. 15 is a cross-sectional view of an embodiment of a light-emitting structure.

Referring to FIG. 15, the light-emitting structure EMS′ may have a tandem structure in which the first to third light-emitting units EU1′ to EU3′ are stacked. In other words, the light-emitting structure EMS′ may have a three stack tandem structure.

Each of the first to third light-emitting units EU1′ to EU3′ may include a light-emitting layer which generates light according to the applied current. The first light-emitting unit EU1′ may include a first light-emitting layer EML1′, a first electron-transporting unit ETU1′, and a first hole-transporting unit HTU1′. The first light-emitting layer EML1′ may be disposed between the first electron-transporting unit ETU1′ and the first hole-transporting unit HTU1′. The second light-emitting unit EU2′ may include a second light-emitting layer EML2′, a second electron-transporting unit ETU2′, and a second hole-transporting unit HTU2′. The second light-emitting layer EML2′ may be disposed between the second electron-transporting unit ETU2′ and the second hole-transporting unit HTU2′. The third light-emitting unit EU3′ may include a third light-emitting layer EML3′, a third electron-transporting unit ETU3′, and a third hole-transporting unit HTU3′. The third light-emitting layer EML3′ may be disposed between the third electron-transporting unit ETU3′ and the third hole-transporting unit HTU3′.

Each of the first to third hole-transporting units HTU1′ to HTU3′ may include at least one of a hole injection layer and a hole transport layer, and may further include a hole buffer layer, an electron-blocking layer, or the like as desired. The first to third hole-transporting units HTU1′ to HTU3′ may have the same configuration or different configurations from each other.

Each of the first to third electron-transporting units ETU1′ to ETU3′ may include at least one of an electron injection layer and an electron transport layer, and may further include an electron buffer layer, a hole-blocking layer, or the like as desired. The first to third electron-transporting units ETU1′ to ETU3′ may have the same configuration or different configurations from each other.

A first charge generation layer CGL1′ is disposed between the first and second light-emitting units EU1′ and EU2′. A second charge generation layer CGL2′ is disposed between the second and third light-emitting units EU2′ and EU3′.

The first to third light-emitting layers EML1′ to EML3′ may generate light of different colors. The light emitted from each of the first to third light-emitting layers EML1′ to EML3′ may be mixed and viewed as white light. In an embodiment, the first light-emitting layer EML1′ may generate blue light, the second light-emitting layer EML2′ may generate green light, and the third light-emitting layer EML3′ may generate red light, for example. However, the disclosure is not limited to the aforementioned embodiment, and two or more light-emitting layers among the first to third light-emitting layers EML1′ to EML3′ may generate light of a same color.

Unlike shown in FIGS. 14 and 15, the light-emitting structure EMS of FIGS. 12 and 13 may include one light-emitting unit in each of the emission areas (e.g., the first and second emission areas EMA1 and EMA2). The light-emitting units disposed in each of the first and second emission areas EMA1 and EMA2 may emit light of different colors. In an embodiment, a light-emitting unit disposed in the first emission area EMA1 may emit red light, and a light-emitting unit disposed in the second emission area EMA2 may emit green light, for example. In this case, unlike in FIGS. 12 and 13, the light-emitting units may be separated from each other.

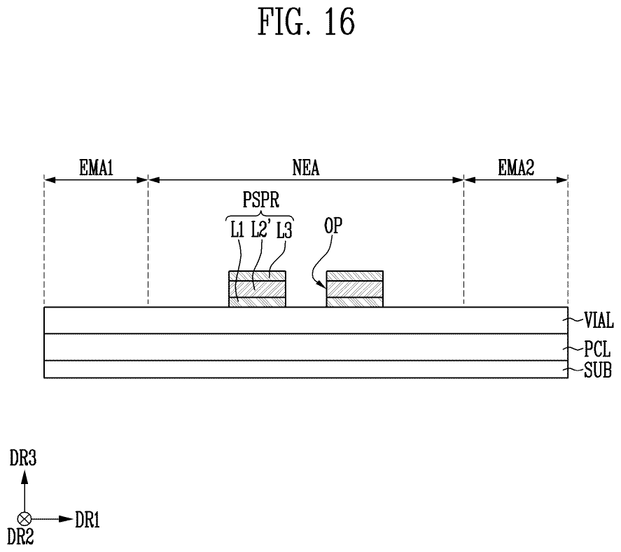

FIGS. 16 to 20 are cross-sectional views schematically illustrating an embodiment of a method of manufacturing a display device.

Referring to FIG. 16, a pre-separator PSPR may be formed on the via layer VIAL in the non-emissive area NEA. In an embodiment, the pre-separator PSPR may include a first layer L1, a sacrificial layer L2′, and a third layer L3, for example. The pre-separator PSPR may define an opening OP therein.

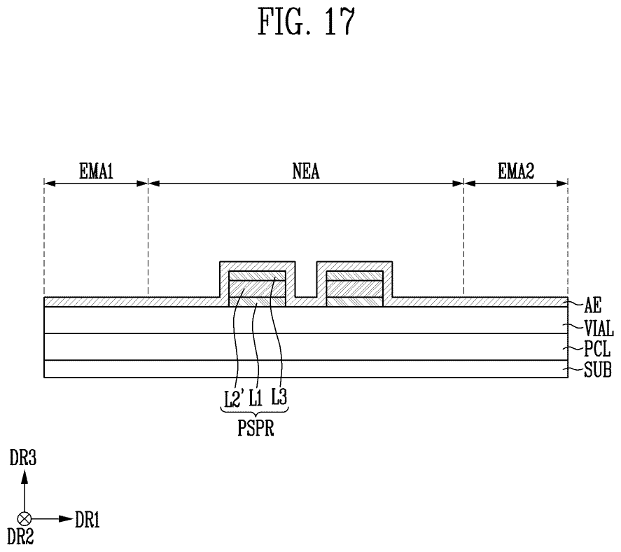

Referring to FIG. 17, the anode AE may be formed over the first and second emission areas EMA1 and EMA2 and the non-emissive area NEA. In an embodiment, the anode AE may be formed to cover the via layer VIAL and the pre-separator PSPR, for example.

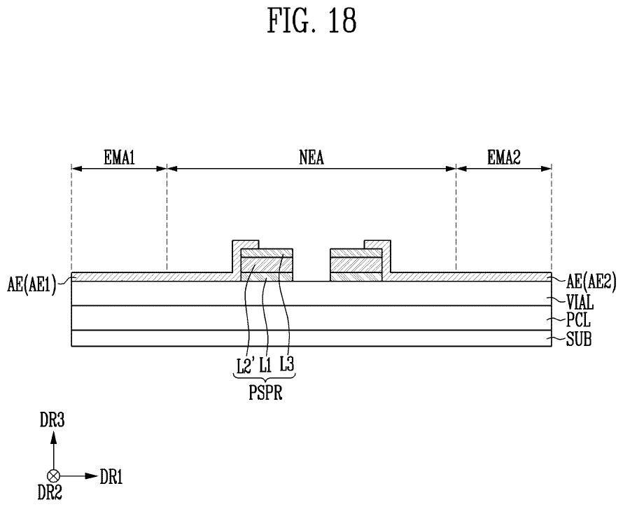

Referring to FIG. 18, the anode AE may be etched and patterned in the non-emissive area NEA. In an embodiment, the anode AE may be separated into a first anode AE1 corresponding to the first emission area EMA1 and a second anode AE2 corresponding to the second emission area EMA2, for example. Each of the anodes AE may also be patterned to include a step in the non-emissive area NEA. As the anode AE is etched, a portion of an upper surface of the pre-separator PSPR (or an upper surface of the third layer L3) and an inner surface of the pre-separator PSPR may be opened.

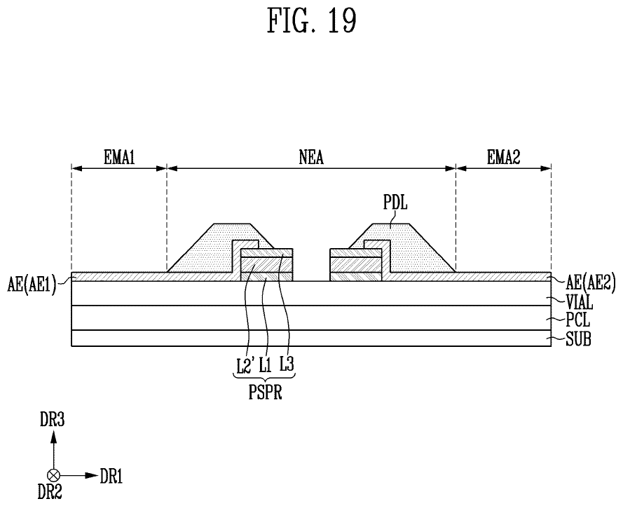

Referring to FIG. 19, a pixel-defining layer PDL may be formed in the non-emissive area NEA. In an embodiment, the pixel-defining layer PDL may be formed to cover a portion of the upper surface of the pre-separator PSPR (or the upper surface of the third layer L3) and the anodes AE, which are disposed in the non-emissive area NEA, for example.

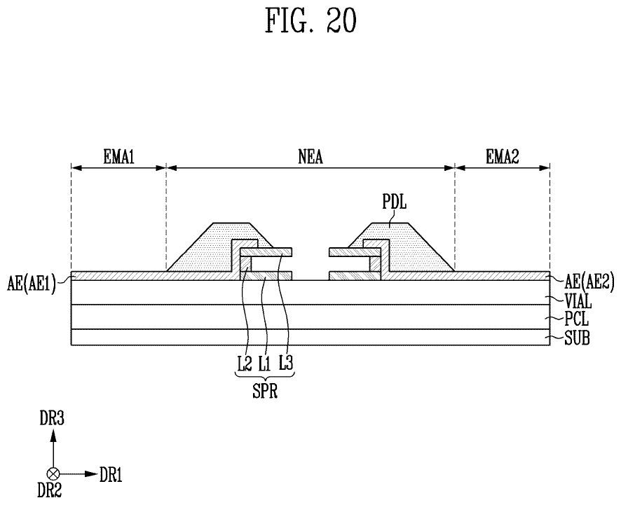

Referring to FIG. 20, the sacrificial layer L2′ (refer to FIG. 19) may be etched to form a separator SPR. The separator SPR, which includes the first layer L1, the third layer L3 and a second layer L2 having a structure that is recessed outward relative to the first and third layers L1 and L3, may be formed.

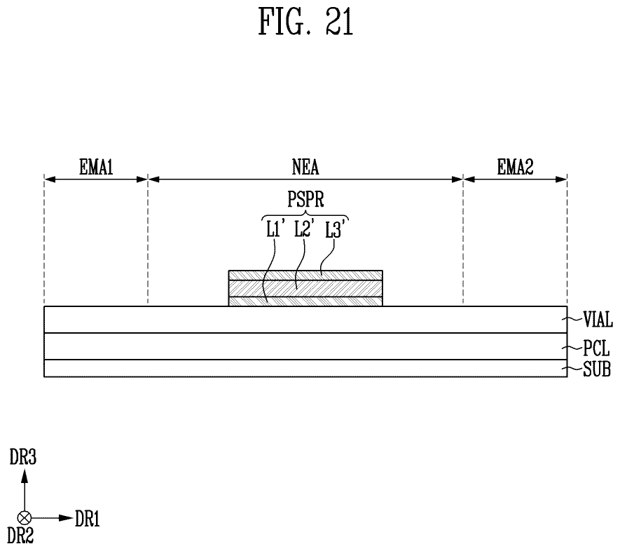

FIGS. 21 to 25 are cross-sectional views schematically illustrating an embodiment of a method of manufacturing a display device.

Referring to FIG. 21, a pre-separator PSPR may be formed on the via layer VIAL in the non-emissive area NEA. In an embodiment, the pre-separator PSPR may include a first sacrificial layer L1′, a second sacrificial layers L2′, and a third sacrificial layer L3′, for example.

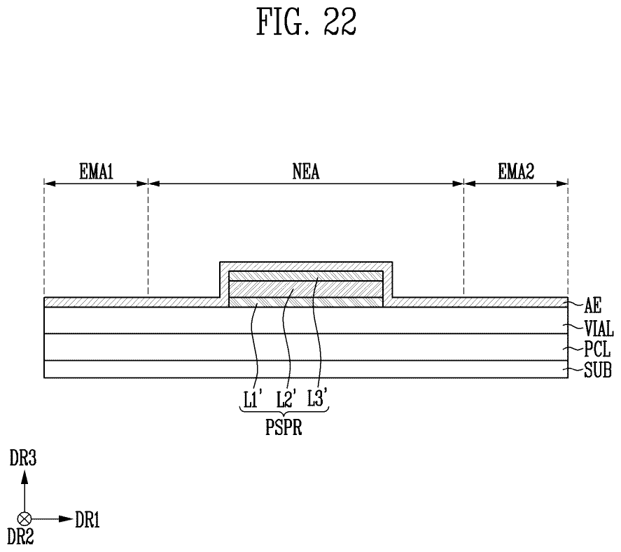

Referring to FIG. 22, the anode AE may be formed over the first and second emission areas EMA1 and EMA2 and the non-emissive area NEA. In an embodiment, the anode AE may be formed to cover the via layer VIAL and the pre-separator PSPR, for example.

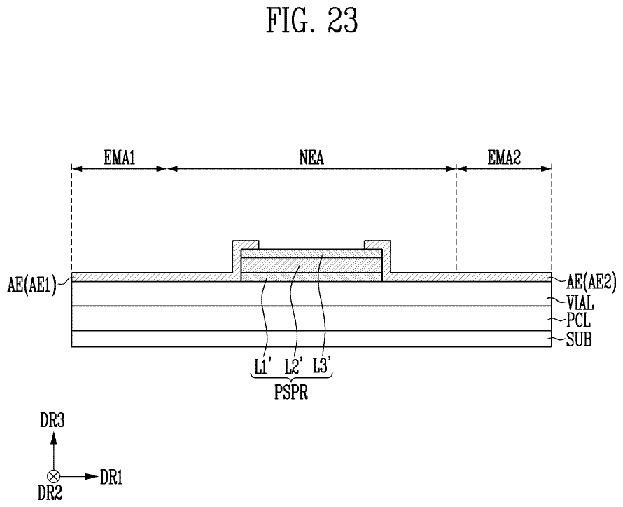

Referring to FIG. 23, the anode AE may be etched and patterned in the non-emissive area NEA. In an embodiment, the anode AE may be separated into a first anode AE1 corresponding to the first emission area EMA1 and a second anode AE2 corresponding to the second emission area EMA2, for example. Each of the anodes AE may be patterned to include a step in the non-emissive area NEA. As the anode AE is etched, a portion of an upper surface of the pre-separator PSPR (or an upper surface of the third sacrificial layer L3′) may be opened.

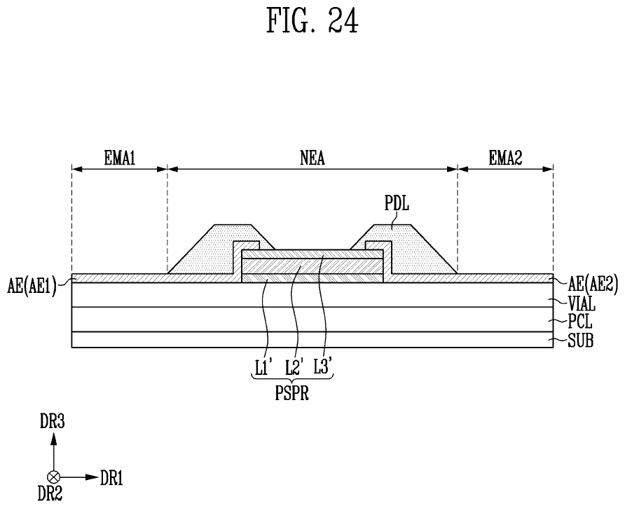

Referring to FIG. 24, a pixel-defining layer PDL may be formed in the non-emission area NEA. In an embodiment, the pixel-defining layer PDL may be formed to cover a portion of the upper surface of the pre-separator PSPR (or the upper surface of the third sacrificial layer L3′) and the anodes, which are disposed in the non-emissive area NEA, for example.

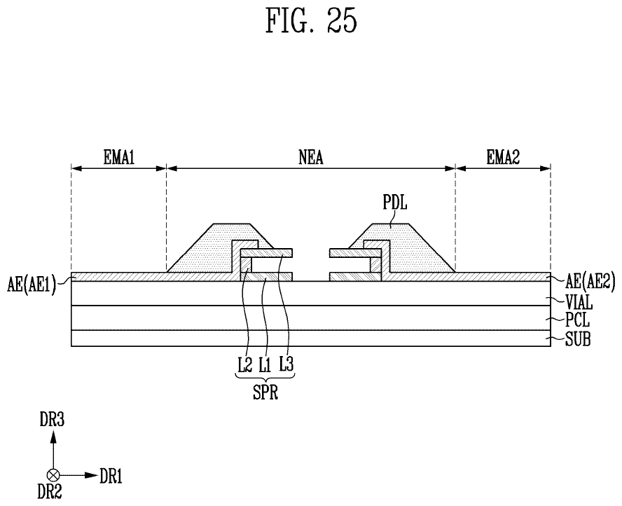

Referring to FIG. 25, a separator SPR may be formed by etching the first to third sacrificial layers L1′ to L3′ (refer to FIG. 24). In an embodiment, the second sacrificial layer L2′ may be etched more than the first and third sacrificial layers L1′ and L3′ due to the relatively high etch ratio, for example. The separator SPR, which includes a first layer L1, a third layer L3 and a second layer L2 having a structure that is recessed outward relative to the first and third layers L1 and L3, may be formed.

A display device in embodiments of the disclosure is applicable to various types of electronic devices. In an embodiment, an electronic device includes the above-described display device and may further include other modules or devices having additional functions in addition to the display device.

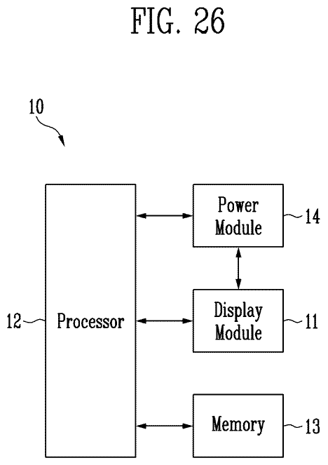

FIG. 26 is a block diagram of an embodiment of an electronic device.

Referring to FIG. 26, the electronic device 10 may include a display module 11, a processor 12, a memory 13, and a power module 14.

The processor 12 may include a circuitry, e.g., at least one of a central processing unit (“CPU”), an application processor (“AP”), a graphic processing unit (“GPU”), a communication processor (“CP”), an image signal processor (“ISP”), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device in embodiments as described above. In addition, in terms of functionality, some of the individual modules included in one module may be included in the display device and others may be provided separately from the display device. In an embodiment, the display module 11 is included in the display device, whereas the processor 12, the memory 13, and the power module 14 are not included in the display device and are instead provided separately in the electronic device 10, for example.

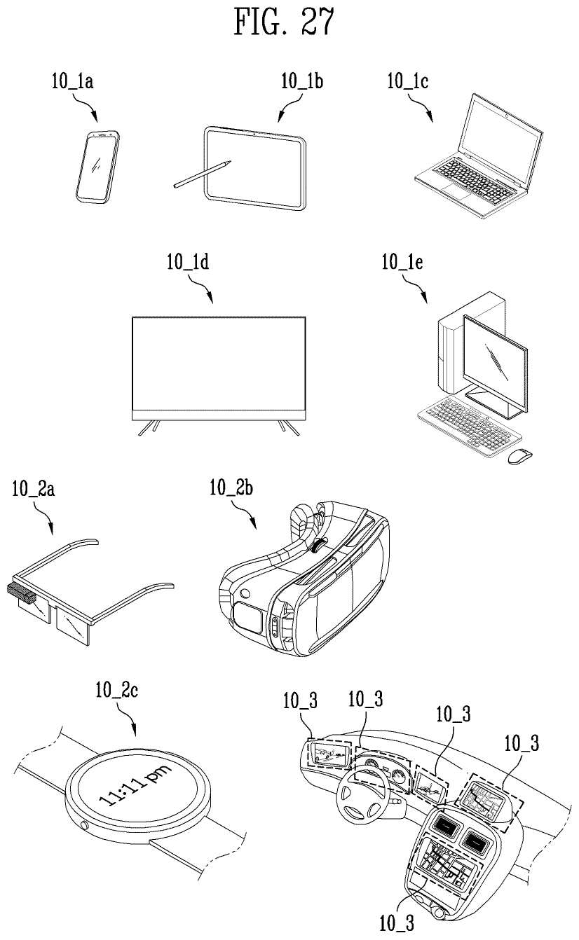

FIG. 27 shows schematic views of an embodiment of an electronic device.

Referring to FIG. 27, various types of electronic devices to which embodiments of a display device are applied may include an electronic device that displays images such as a smartphone 10_1a, a tablet personal computer (“PC”) 10_1b, a laptop computer 10_1c, a television (“TV”) 10_1d, and a desktop monitor 10_1e, a wearable electronic device including a display module such as smart glasses 10_2a, a head-mounted display (“HMD”) 10_2b, and a smart watch 10_2c, and an automotive electronic device 10_3 including a display module such as a center information display (“CID”) disposed at the instrument cluster, the center fascia, and the dashboard of a vehicle, and a room mirror display.

In the display device and the electronic device in embodiments of the disclosure, a highly conductive layer of a light-emitting structure may be disconnected by a separator having a multi-layered structure in a non-emissive area. As a result, leakage current generated between sub-pixels next (adjacent) to each other may be reduced or eliminated.

The effects of the disclosure are not limited by the foregoing, and other various effects are anticipated herein.

While the disclosure has been particularly shown and described with reference to embodiments thereof, it will be understood by those of ordinary skill in the art that various changes in form and detail may be made therein without departing from the spirit and scope of the disclosure as defined by the following claims.

What is claimed is:

1. A display device in which emission areas and a non-emissive area are defined, the display device comprising:
anodes disposed in the emission areas, respectively, and spaced apart from each other;
a separator disposed between the anodes in the non-emissive area, the separator comprising:
a first layer having a first width;
a second layer disposed on the first layer and having a second width; and
a third layer disposed on the second layer and having a third width; and
a pixel-defining layer disposed on the anodes and the separator in the non-emissive area.

2. The display device of claim 1, wherein, in the non-emissive area, the anodes contact at least a portion of the separator.

3. The display device of claim 2, wherein the anodes contact an outer surface of the first layer, an outer surface of the second layer, and a portion of an upper surface and an outer surface of the third layer.

4. The display device of claim 3, wherein the pixel-defining layer contacts another portion of the upper surface of the third layer.

5. The display device of claim 2, wherein the anodes contact a portion of an outer surface of the first layer.

6. The display device of claim 5, wherein the first layer and the third layer each include a step.

7. The display device of claim 6, wherein the pixel-defining layer contacts another portion of the outer surface of the first layer, an outer surface of the second layer, and a portion of an upper surface and an outer surface of the third layer.

8. The display device of claim 2, wherein the anodes contact a portion of a lower surface of the first layer.

9. The display device of claim 8, wherein the pixel-defining layer contacts an outer surface of the first layer, an outer surface of the second layer, and a portion of an upper surface and an outer surface of the third layer.

10. The display device of claim 1, wherein, in the non-emissive area, the separator is spaced apart from the anodes.

11. The display device of claim 10, wherein at least a portion of the pixel-defining layer is disposed between the separator and each of the anodes.

12. The display device of claim 1, wherein the first width and the third width are greater than the second width, and the first width is equal to the third width.

13. The display device of claim 1, wherein the first width is greater than the third width, and the third width is greater than the second width.

14. The display device of claim 1, wherein the third width is greater than the first width, and the first width is greater than the second width.

15. The display device of claim 1, wherein the third width is greater than the second width, and the second width is greater than the first width.

16. The display device of claim 1, wherein the display device further comprises:
a light-emitting structure disposed on the anodes, the pixel-defining layer, and the third layer;
a cathode on the light-emitting structure;
a capping layer on the cathode; and
an encapsulation layer on the capping layer.

17. The display device of claim 16, wherein the display device further comprises an auxiliary electrode disposed between the capping layer and the encapsulation layer.

18. An electronic device comprising:
a display device in which emission areas and a non-emissive area are defined, the display device comprising:
anodes disposed in the emission areas, respectively, and spaced apart from each other;
a separator disposed between the anodes in the non-emissive area, the separator comprising:
a first layer having a first width;
a second layer disposed on the first layer and having a second width; and
a third layer disposed on the second layer and having a third width; and
a pixel-defining layer disposed on the anodes and the separator in the non-emissive area; and
a processor configured to operate the display device.

19. The electronic device of claim 18, wherein the anodes contact at least a portion of the separator.

20. The electronic device of claim 18, wherein the separator is spaced apart from the anodes.
